(19) United States
(12) Patent Application Publication
(10) Pub. No.: US 2025/0218960 A1
(43) Pub. Date: Jul. 3, 2025

(54) METHODS AND APPARATUS TO EMBED SEMICONDUCTOR DEVICES IN CORES OF PACKAGE SUBSTRATES

(71) Applicant: Intel Corporation, Santa Clara, CA (US)

(72) Inventors: Clay Bradley Arrington, Queen Creek, AZ (US); Kyle Jordan Arrington, Gilbert, AZ (US); Yiqun Bai, Chandler, AZ (US); Ryan Joseph Carrazzone, Chandler, AZ (US); Haobo Chen, Chandler, AZ (US); Gang Duan, Chandler, AZ (US); Hongxia Feng, Chandler, AZ (US); Mohit Gupta, Chandler, AZ (US); Wei Li, Chandler, AZ (US); Ziyin Lin, Chandler, AZ (US); Xiao Liu, Chandler, AZ (US); Brandon Christian Marin, Gilbert, AZ (US); Robert Alan May, Chandler, AZ (US); Kyle Matthew McElhinny, Tempe, AZ (US); Yongki Min, Phoenix, AZ (US); Bai Nie, Chandler, AZ (US); Srinivas Venkata Ramanuja Pietambaram, Chandler, AZ (US); Bohan Shan, Chandler, AZ (US); Hiroki Tanaka, Gilbert, AZ (US); Jose Fernando Waimin Almendares, Gilbert, AZ (US); Dingying Xu, Chandler, AZ (US)

(21) Appl. No.: 18/399,185

(22) Filed: Dec. 28, 2023

(51) Int. Cl. H01L 23/538; H01L 23/00; H01L 23/31; H01L 23/64; H01L 25/065

(52) U.S. Cl. CPC H01L 23/5386; H01L 23/3121; H01L 23/5383; H01L 23/642; H01L 24/32; H01L 25/0652; H01L 24/16; H01L 2224/16225; H01L 2224/32225

(57) ABSTRACT

Systems, apparatus, articles of manufacture, and methods to embed semiconductor devices in cores of package substrates are disclosed. An example package substrate includes a core having a first surface and a second surface. The core includes a cavity extending between the first and second surfaces. The example package substrate further includes a semiconductor die within the cavity; a pedestal within the cavity; and an adhesive within the cavity. The adhesive surrounds the semiconductor die and the pedestal. A material of the pedestal different from a material of the adhesive.

### FIELD OF THE DISCLOSURE

This disclosure relates generally to semiconductor packages and, more particularly, to methods and apparatus to embed semiconductor devices in cores of package substrates.

### BACKGROUND

In many electronic devices, integrated circuit (IC) chips and/or semiconductor dies are connected to larger circuit boards such as motherboards and/or other types of printed circuit boards (PCBs) via a package substrate. Some known IC packages utilize voltage regulators for power delivery applications. In some instances, capacitors and/or other components used for such voltage regulators can be included in the package substrate for an IC package.

### BRIEF DESCRIPTION OF THE DRAWINGS

FIG. 1 illustrates an example integrated circuit (IC) package constructed in accordance with teachings disclosed herein.

FIG. 2 illustrates an example implementation of the package substrate of FIG. 1 in which the semiconductor device is supported on an example pedestal within the cavity of the substrate core.

FIG. 3 illustrates another example implementation of the package substrate of FIG. 1 in which the semiconductor device is supported on an example pedestal within the cavity of the substrate core.

FIG. 4 is a flowchart representative of an example method to manufacture the example package substrate of FIG. 1 according to the example implementation of FIG. 2.

FIGS. 5-16 illustrate the example package substrate at different stages during the example method of manufacture of FIG. 4.

FIG. 17 is a flowchart representative of an example method to manufacture the example package substrate of FIG. 1 according to the example implementation of FIG. 3.

FIGS. 18-27 illustrate the example package substrate of FIG. 1 at different stages during the example method of manufacture of FIG. 17.

FIG. 28 is a top view of a wafer including dies that may be included in an IC package constructed in accordance with teachings disclosed herein.

FIG. 29 is a cross-sectional side view of an IC device that may be included in an IC package constructed in accordance with teachings disclosed herein.

FIG. 30 is a cross-sectional side view of an IC device assembly that may include an IC package constructed in accordance with teachings disclosed herein.

FIG. 31 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

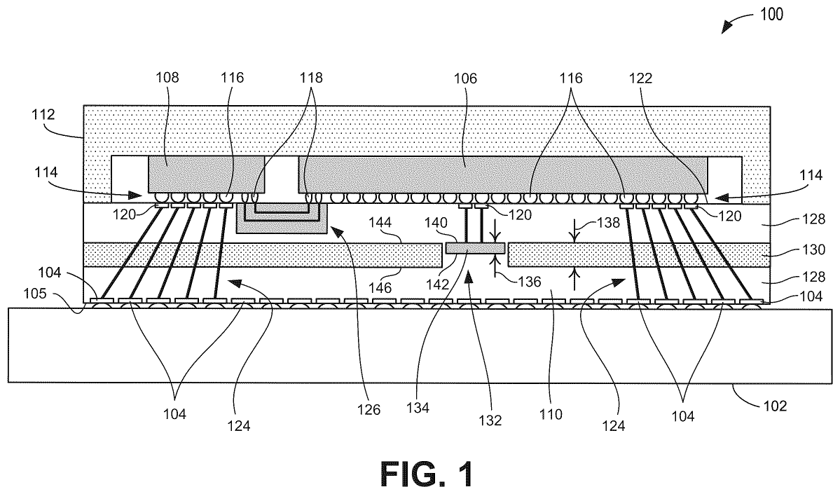

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path (e.g., a continuous electrical signal path) between the interconnects 114 of the dies 106, 108 and the pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within build-up regions 128 on one or both sides of a substrate core 130 in the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is an organic substrate or core (e.g., an epoxy-based prepreg layer). In other examples, the substrate core 130 is a glass substrate or core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In some examples, glass substrates (e.g., the glass core 130) include at least one glass layer and do not include epoxy and do not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plan view, with the layers above and below the core (e.g., substantially coextensive with the build-up regions 128). The substrate core 130, whether an organic core or a glass core, provides stiffness and mechanical support or strength for the package substrate 110 and the rest of the package 100. Thus, the substrate core 130 is an example means for strengthening the package substrate 110. In some examples, the thickness of the core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

As shown in the illustrated example, the substrate core 130 includes a cavity 132 (e.g., an opening, a recess, etc.) in which a semiconductor device 134 is embedded. In some examples, the semiconductor device 134 is a passive semiconductor die (e.g., a die that does not include transistors but implements passive circuitry (e.g., capacitor(s), inductor(s), resistor(s), etc.)). In some examples, the semiconductor device 134 is an active semiconductor die (e.g., includes transistors). In the example of FIG. 1, the semiconductor device 134 is a deep trench capacitor die (also referred to herein as a deep trench capacitor, or simply capacitor, for short). In some such examples, the deep trench capacitor is used to enable efficient power delivery to a fully integrated voltage regulator within the first die 106 in the IC package 100. In other examples, other types of semiconductor devices can be embedded within the cavity 132 of the substrate core 130 in addition to or instead of a deep trench capacitor (e.g., inductors, resistors, etc.). In some examples, more than one semiconductor device 134 can be embedded within the cavity 132 of the substrate core 130. In some examples, the substrate core 130 can include multiple cavities each containing one or more separate semiconductor devices 134.

As shown in the illustrated example, the semiconductor device 134 is electrically coupled to the first die 106. In some examples, the semiconductor device 134, as a deep trench capacitor, is positioned in close proximity to the first die 106 (e.g., within the substrate core 130 rather than spaced farther away like land-side capacitors) to reduce inductance and parasitic effects, thereby increasing the effectiveness of the capacitor (and/or achieving a given capacitance with a smaller sized capacitor). However, a challenge with embedding a semiconductor device 134 within a core 130 of a substrate arises from the thickness mismatch between the semiconductor device 134 and the core 130. In this example, the semiconductor device 134 is constructed through wafer-level processing from a semiconductor (e.g., silicon) wafer. Due to the nature of such wafer-level processing, the semiconductor device 134 has a thickness 136 limited to less than or equal to approximately 800 micrometers (μm) or less (e.g., less than or equal to approximately 700 μm, less than or equal to approximately 650 μm, less than or equal to approximately 600 μm, etc.). By contrast, the substrate core 130 can be significantly thicker, especially for larger packages as noted above. For instance, in some examples, the core 130 has a thickness 138 that is at least 20% greater than the thickness 136 of the semiconductor device 134 or more (e.g., at least 25% greater, at least 30% greater, at least 50% greater, at least 75% greater, at least twice as great, etc.). More specifically, in some examples, the thickness 138 of the core 130 is greater than approximately 800 μm or more (e.g., greater than or equal to approximately 900 μm, greater than or equal to approximately 1 millimeter (mm) (e.g., 1000 μm), greater than or equal to approximately 1.2 mm, greater than or equal to approximately 1.4 mm, greater than or equal to approximately 1.5 mm, etc.). Thus, as shown in FIG. 1, the thickness 136 of the semiconductor device 134 (e.g., defined by a first die surface 140 and a second die surface 142 opposite the first die surface 142) is less than the thickness 138 of the core 130 (e.g., defined by a first core surface 144 and a second core surface 146 opposite the first core surface 144).

The mismatch between the thicknesses 136, 138 of the semiconductor device 134 and the core 130 presents challenges in positioning the semiconductor device 134 within the cavity 132 of the core 130. Specifically, the relatively small size of the semiconductor device 134 can result in misalignments in any of the x, y, and z axes and/or rotational shifting or tilting because of the difficulty in securing the semiconductor device 134 in place. In particular, the use of adhesives and/or an encapsulant to hold the semiconductor device 134 in place can be difficult because of the large space within the cavity 132 that needs to be filled which can result in a relatively long time for the adhesive and/or encapsulant to set or cure during which the semiconductor device 134 may shift, rotate, or otherwise move. As a result, the first die surface 140 of the semiconductor device 134 (e.g., a contact surface containing contacts with which the semiconductor device 134 is electrically coupled to (and facing towards) the first die 106) may not be aligned (e.g., flush) with a corresponding and/or adjacent surface of the substrate core 130 (e.g., the first core surface 144 also facing towards the first die 106). Such misalignment can negatively affect the ability of the semiconductor device 134 to electrically connect with the interconnects within the build-up region 128 above the core 130. Furthermore, the non-homogeneity of materials within the cavity 132 (e.g., the semiconductor device 134 and a relatively large volume of adhesive and/or encapsulant) can create processing challenges downstream and/or increase risks of warpage and/or mechanical stress in the package substrate 110.

Examples disclosed herein overcome the above challenges by providing a pedestal, spacer, platform, or other structure to fill much of the space within the cavity 132. In this way, less adhesive and/or encapsulant is needed to fill in any remaining space in the cavity to hold the semiconductor device 134 (and the pedestal) in position, thereby reducing the curing time and/or otherwise simplifying the fabrication and/or assembly process and reducing other negative downstream effects of large volumes of adhesive (e.g., warpage, stress, etc.). Furthermore, in some examples, the pedestal is dimensioned with a thickness to support the semiconductor device 134 during fabrication and/or assembly so as to place the first die surface 140 of the semiconductor device 134 substantially flush with first core surface 144. As used herein, substantially flush means less than 5 degrees of tilt or angular offset or less (e.g., e.g., less than 2 degrees of angular offset, less than 1 degree of angular offset, etc.) between the surfaces and/or within 25 μm of misalignment or less (e.g., less than 20 μm of misalignment, less than 15 μm of misalignment, less than 10 μm of misalignment, etc.). That is, in some examples, the manufacturing process includes first mounting the semiconductor device 134 to a pedestal so that the combined thickness of the components substantially fills the cavity 132 and positions the first die surface 140 of the semiconductor device 134 adjacent to (e.g. aligned with) the first core surface 144 of the core prior to filling the cavity 132 with an adhesive and/or encapsulant. In other words, the pedestal helps to support or secure the semiconductor device 134 in place while the adhesive and/or encapsulant is added and cured.

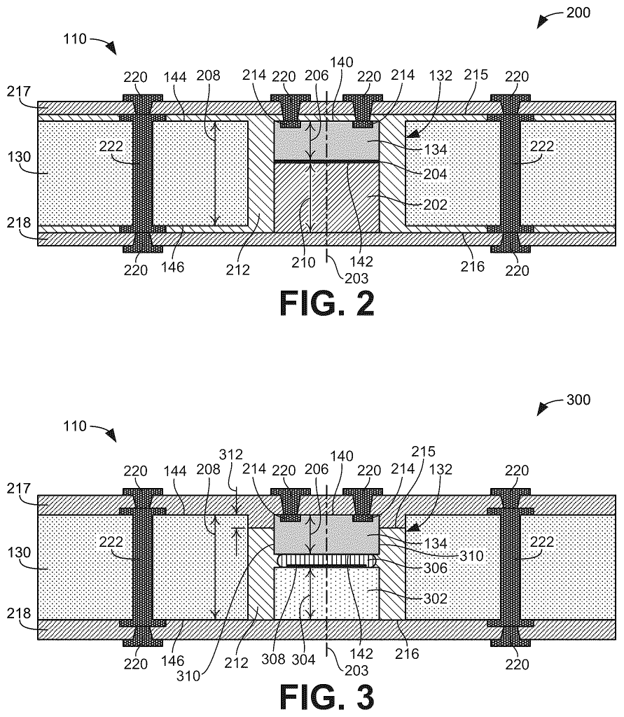

FIG. 2 illustrates an example implementation 200 of the package substrate 110 of FIG. 1 in which the semiconductor device 134 (e.g., a semiconductor die, a deep trench capacitor) is supported on an example pedestal 202 (e.g., a spacer, a platform, etc.) within the cavity 132 of the substrate core 130. In this example, the semiconductor device 134 and the pedestal are stacked along a through-axis 203 of the cavity 132. More particularly, in this example, the second die surface 140 of the semiconductor device 134 is attached to the pedestal 202 with an adhesive 204 (e.g., a die attach film). Although the width of the semiconductor device 134 is shown as being the same as the width of the pedestal 202, in some examples, the pedestal 202 is larger (e.g., wider) than the semiconductor device 134. In other examples, the semiconductor device 134 is larger (e.g., wider) than the pedestal 202.

In the illustrated example of FIG. 2, the semiconductor device 134 has a thickness 206 between the first die surface 140 and the second die surface 142. As discussed above, the thickness 206 of the semiconductor device 134 is less than a thickness 208 of the core 130 defined between the first core surface 144 and the second core surface 146. In this example, the pedestal has a thickness 210 that substantially spans the difference between the thicknesses 206, 208. That is, in this example, the pedestal spans substantially a full distance (e.g., a majority of the distance) through the cavity 132 that is not taken up by the thickness 206 of the semiconductor device 134. More particularly, in this example, the semiconductor device 134 and the pedestal 202 meet at an interface (where the adhesive 204 is applied) within the cavity with the first die surface 140 of the semiconductor device 134 substantially flush with the first core surface 144 of the core 130 and the pedestal 202 extending slightly beyond the cavity 132 adjacent the second core surface 146.

In this example, the stack-up of the semiconductor device 134 and the pedestal 202 are surrounded by (e.g., encapsulated by) another adhesive material 212. In some examples, the adhesive material 212 that surrounds the semiconductor device 134 and the pedestal 202 is different than the adhesive 204 used to attach the semiconductor device 134 to the pedestal 202. In some examples, the adhesive material 212 is an epoxy, a mold compound, or other encapsulant that is dispensed as a liquid and subsequently cured or hardened to secure the position of the semiconductor device 134 and the pedestal 202 within the cavity 132. As shown in the illustrated example, the adhesive material 212 extends beyond the cavity 132 to cover portion(s) of the first and second core surfaces 144, 146. That is, the adhesive material 212 spans a distance between a first adhesive surface 215 adjacent to (but beyond) the first core surface 144 and a second adhesive surface 216 adjacent to (but beyond) the second core surface 146. In other examples, the adhesive material 212 may be limited to areas within the cavity 132 (e.g., the first and second adhesive surfaces 215, 216 may be flush with and/or recessed relative to the corresponding first and second core surfaces 144, 146). In other examples, the adhesive material 212 may be limited within one end of the cavity 132 but extend beyond the other end to cover portions of one of the first or second core surfaces 144, 146.

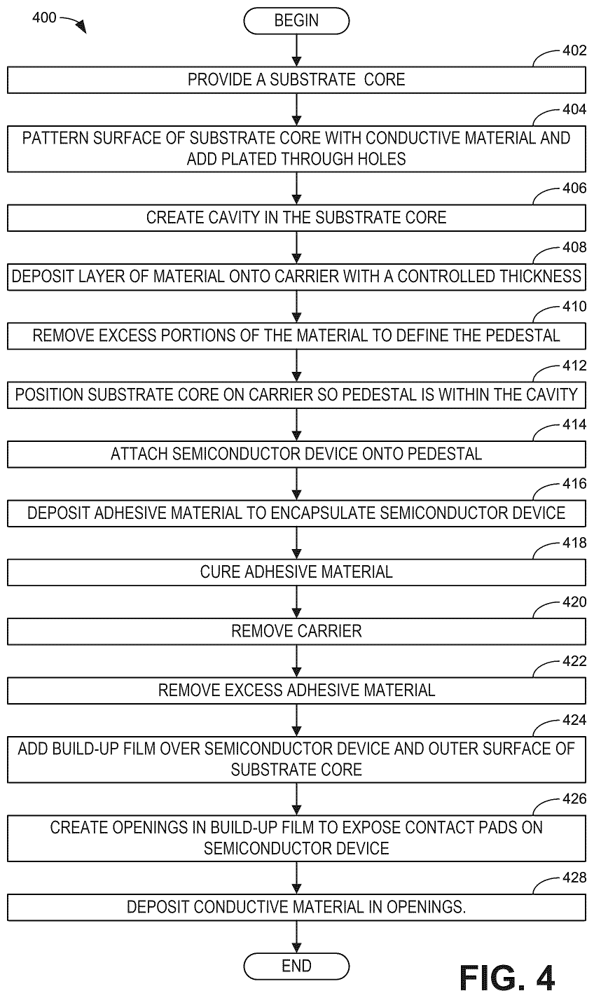

In some examples, the pedestal 202 is composed of a material that is different than the surrounding adhesive material 212. More particularly, in some examples, the pedestal 202 is composed of a material that can be deposited in a controlled manner so as to precisely control the thickness 210 of the pedestal 202. For instance, in some example, the pedestal 202 is composed of a dry film resist. In some examples, the pedestal is composed of a photo-imageable dielectric. The formation of the pedestal 202 with such materials is described further below in connection with FIGS. 4, 8, and 9. The thickness 210 of the pedestal 202 is defined by the thickness 206 of the semiconductor device 134 relative to the thickness 208 of the core 130. Specifically, in some examples, the thickness 210 of the pedestal is controlled so that when the semiconductor device 134 is stacked thereon, the first die surface 140 of the semiconductor device 134 is substantially flush (e.g., aligned with) the first core surface 144. As a result, in this example, contact pads 214 on the first die surface 140 of the semiconductor device 134 are also aligned with the first core surface 144. In the illustrated example, the contact pads 214 are flush with the rest of the first die surface 140. However, in other examples, the contact pads 214 can be recessed relative to or protrude from the rest of the die surface 140.

In the illustrated example of FIG. 2, a first dielectric layer 217 is shown on (e.g., adjacent) the first core surface 144 and a second dielectric layer 218 is shown on (e.g., adjacent) the second core surface 146. More particularly, in this example, the first dielectric layer 217 is positioned on (e.g., in contact with) the first adhesive surface 215, and the second dielectric layer 218 is positioned on (e.g., in contact with) the second adhesive surface 216. The first and second dielectric layers 217, 218 correspond to the initial layers of the build-up regions 128 on either side of the core 130 shown in FIG. 1. Further, in the illustrated example of FIG. 2, a plurality of different vias 220 extending through the dielectric layers 217, 218. In this example, ones of the vias 220 extend through the first dielectric layer 217 and the portion of the adhesive material 212 covering the first surface 140 of the semiconductor device 134 to electrical couple with the contact pads 214. Other ones of the vias 220 are electrical coupled to plated through holes (PTHs) 222 extending through the substrate core 130.

FIG. 3 illustrates another example implementation 300 of the package substrate 110 of FIG. 1 in which the semiconductor device 134 (e.g., a semiconductor die, a deep trench capacitor) is supported on an example pedestal 302 (e.g., a spacer, a platform, etc.) within the cavity 132 of the substrate core 130. The features shown in FIG. 3 that are the same or similar to corresponding features shown in FIG. 2 are identified by the same reference numbers. Further, the detailed description of such features provided above in connection with FIG. 2 apply equally to the corresponding features shown in FIG. 3 and, thus, will not be repeated here.

The example implementation 300 of FIG. 3 differs from the example implementation 200 of FIG. 2, in that the pedestal 302 of FIG. 3 has a smaller thickness 304 than the thickness 210 of the pedestal 202 of FIG. 2. Thus, in the illustrated example of FIG. 3, the pedestal 302 spans less than the full distance along the cavity 132 corresponding to the difference between the thickness 206 of the semiconductor device 134 and the thickness 208 of the core 130. In this example, the remaining distance along the length of the cavity 132 (e.g., along the through-axis 203) is filled with a compressible material 306. The example compressible material 306 can be any suitable material that can be compressed to produce a reactive force pushing against the force compressing the material. For instance, in some examples, the compressible material 306 is a foam or other porous material (e.g., a polymer mesh). In some examples, the compressible material 306 is a polymer that exhibits relatively large plastic deformation when compressed.

In the illustrated example of FIG. 3, the compressible material 306 is held in compression between the pedestal 302 and the semiconductor device 134. Being in a compressed state, the compressible material 306 produces a reactive force that urges the semiconductor device 134 away from the pedestal 302. However, the adhesive material 212 that surrounds the semiconductor device 134 and the pedestal 302 (as well as the compressible material 306) overcomes the reactive force produced by the compressible material 306 (held in compression) to retain the semiconductor device 134 in a fixed position relative to the pedestal 302.

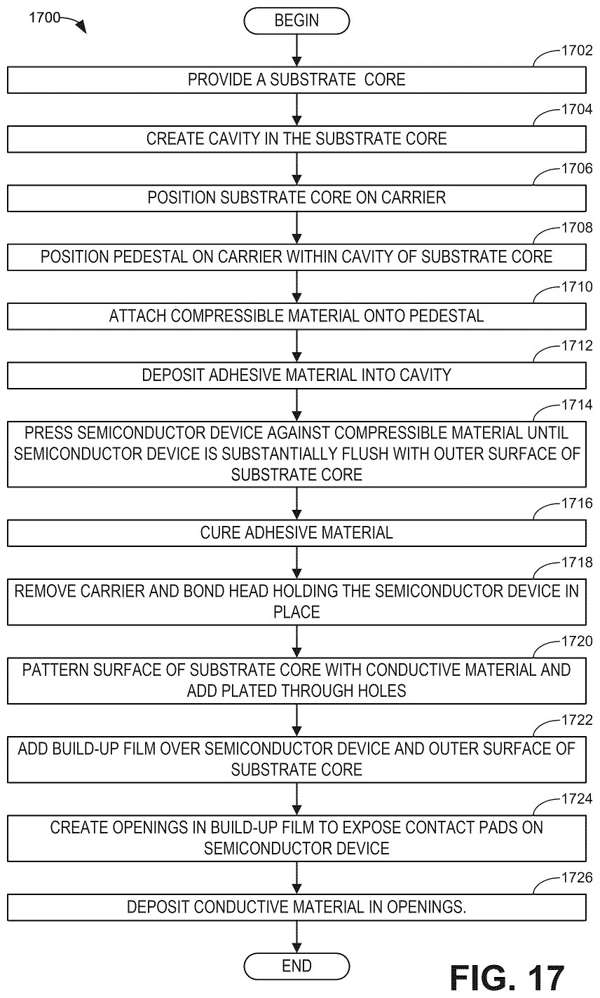

The compressible material 306 facilitates the first die surface 140 of the semiconductor device 134 to be positioned substantially flush with the first core surface 144 of the core 130 without having to precisely control the thickness 304 of the pedestal 302. As explained further below in connection with FIGS. 17 and 20-23, during fabrication and/or assembly of the package substrate 110 of FIG. 3, the compressible material 306 is first attached to the pedestal 302 (e.g., using an adhesive 308) within the cavity 132. Being in an uncompressed state at this point in the manufacturing process, the compressible material 306 will have a greater thickness than is shown in FIG. 3. Thereafter, the cavity 132 is partially filled with the adhesive material 212 to surround the pedestal 302 and the compressible material 306. Then, before the adhesive material 212 sets or hardens, the semiconductor device 134 is pressed down onto the compressible material 306 until the first die surface 140 of the semiconductor device 134 is substantially flush with the first core surface 144. In some examples, the semiconductor device 134 is pressed down by a flat plate (e.g., a bond head) that is larger than the cavity 132 such that the plate will come into contact with the first core surface 144 of the core 130 as a hard stop. With the compressible material 306 in compression, the reactive force produced by the compressible material 306 will urge the semiconductor device 134 upwards against the plate, thereby ensuring the semiconductor device 134 is held substantially flush with the first core surface 144 of the core 130 (against which the plate is pressed). While the semiconductor device 134 is held in this position, the adhesive material 212 is hardened or cured so that once the plate is removed, the semiconductor device 134 will remain in position because the reactive forces of the compressed compressible material 306 cannot overcome the strength of the hardened adhesive material 212. Thus, the semiconductor device 134 can be positioned with the first die surface 140 that is held in a position substantially coplanar to the first core surface 144. As used herein, two surfaces are substantially coplanar when the surfaces are parallel to within 5 degrees or less (e.g., e.g., within 2 degrees, within 1 degree, etc.) and are offset relative to one another by less than 25 μm or less (e.g., 20 μm, 15 μm, 10 μm, etc.).

The reactive forces of the compressible material 306 urging the semiconductor device 134 against a plate as the semiconductor device 134 is pressed into the cavity 132 (thereby subjecting the compressible material 306 to compression) ensures the first die surface 140 of the semiconductor device 134 is flush with the first core surface 144 regardless of the precise height or thickness 304 of the pedestal 302. As a result, the pedestal 302 can be any suitable material that is fabricated in any suitable manner that is not limited to the precise thickness control discussed above in connection with the pedestal 202 of FIG. 2. In some examples, the pedestal 302 of FIG. 3 can be the same material as the pedestal 202 of FIG. 2 (e.g., a dry film resist, a photo-imageable dielectric, etc.). However, in other examples, the pedestal 302 can be any other suitable material (e.g., structural silicon, glass, ceramic, etc.).

Unlike in FIG. 2, in the example implementation 300 of FIG. 3, the adhesive material 212 is limited to locations within the cavity 132. More particularly, in this example, the first adhesive surface 215 is recessed within the cavity 132 relative to the first core surface 144 (and the flush first die surface 140). Further, in this example, the second adhesive surface 216 extends up to (but not beyond) the second core surface 146. In some examples, the first adhesive surface 215 is recessed relative to the first core surface 144 to reduce (e.g., prevent) the adhesive material 212 from contacting and, thus, contaminating the plate (e.g., bond head) used to press the semiconductor device 134 into the cavity 132. However, in some examples, the first adhesive surface 215 is at least closer to the first core surface 144 than the second die surface 142 is to the first core surface 144. That is, in some examples, the adhesive material 212 extends at least part way along (e.g., up) lateral edges 310 of the semiconductor device 134 so as to adhere to the semiconductor device 134 and prevent the compressible material 306 from expanded from its compressed state. In some examples, the adhesive material 212 extends a majority of the distance along the lateral edges 310 of the semiconductor device 134. That is, in some examples, the first adhesive surface 215 is closer to the first die surface 140 than the first adhesive surface 215 is to the second die surface 142. In some examples, the first adhesive surface 215 is a distance 312 from the first core surface that is less than 50 μm. In some examples, the distance 312 is significantly less than 50 μm (e.g., less than 25 μm, less than 10 μm, less than 5 μm, etc.).

Inasmuch as the adhesive material 212 is contained within the cavity 132, the adhesive material 212 does not extend out onto the first and second core surfaces 144, 146. As such, in the illustrated example of FIG. 3, the first and second dielectric layers 217, 218 are in direct contact with the first and second core surfaces 144, 146. However, in some examples, the adhesive material 212 may extend beyond the cavity 132 to cover portions of the second core surface 146 of the core 130 (e.g., similar to what Is show on the bottom side of the example implementation 200 of FIG. 2).

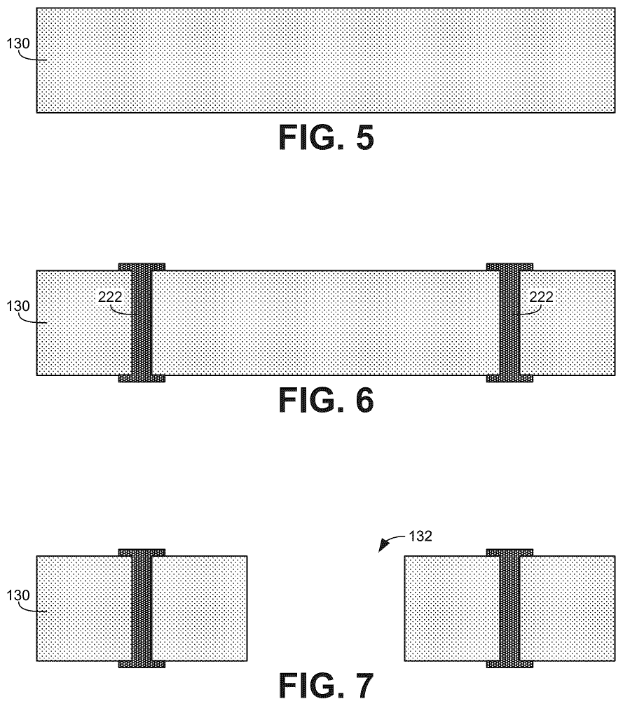

FIG. 4 is a flowchart representative of an example method 400 to produce the example package substrate 100 of FIG. 1 according to the example implementation 200 of FIG. 2. In some examples, some or all of the operations outlined in the example method of FIG. 4 are performed automatically by fabrication equipment that is programmed to perform the operations. Although the example method of manufacture is described with reference to the flowchart illustrated in FIG. 4, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example. FIGS. 5-16 illustrate the example package substrate 110 at different stages of manufacture during the implementation of the method 400 of FIG. 4.

The example method 400 of FIG. 4 begins at block 402 by providing a substrate core. FIG. 5 illustrates the example substrate core 130 at this stage in the manufacturing process. At block 404, the surface of the substrate core 130 is patterned with conductive material (e.g., copper) and plated through holes (PTHs) are added. FIG. 6 illustrates this stage of the manufacturing process with the example PTHs 222 extending through the substrate core 130 (with associated conductive pads at each end). While two PTHs 222 are shown in this illustrated example, any other number of PTHs may be used. Further, any other portions (e.g., traces, pads, etc.) of conductive material can be patterned on one or both surfaces of the core 130. At block 406, a cavity is created in the substrate core 130. FIG. 7 illustrates this stage of the manufacturing process with the cavity 132 extending through the substrate core 130.

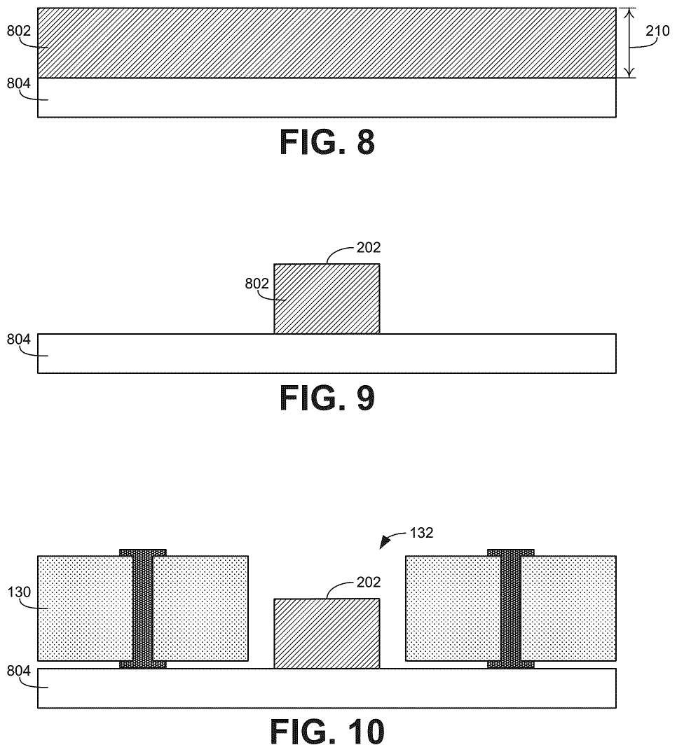

At block 408, a layer of material is deposited onto a carrier with a controlled thickness. FIG. 8 illustrates this stage of the manufacturing process with a layer of material 802 deposited on a carrier 804. In this example, the layer of material 802 is a dry film resist or a photo-imageable dielectric that can be deposited using any suitable deposition process. The layer of material 802 is to serve as the basis for the pedestal 202 of FIG. 2. Accordingly, as shown in FIG. 8, the layer of material 802 has a thickness corresponding to the thickness 210 of the pedestal 202. At block 410, excess portions of the material 802 are removed to define the pedestal. FIG. 9 illustrates this stage of the manufacturing process with the only portion of the layer of material 802 remaining corresponding to the pedestal 202. In this example, the excess portions of the material 802 can be removed using any suitable process (e.g., a wet etch, a dry etch, etc.). Blocks 408 and 410 of FIG. 4 can be performed independent of blocks 402-406. Thus, in some examples, blocks 408 and 410 are implemented prior to blocks 402-406. In other examples, blocks 408 and 410 are implemented in parallel with blocks 402-406.

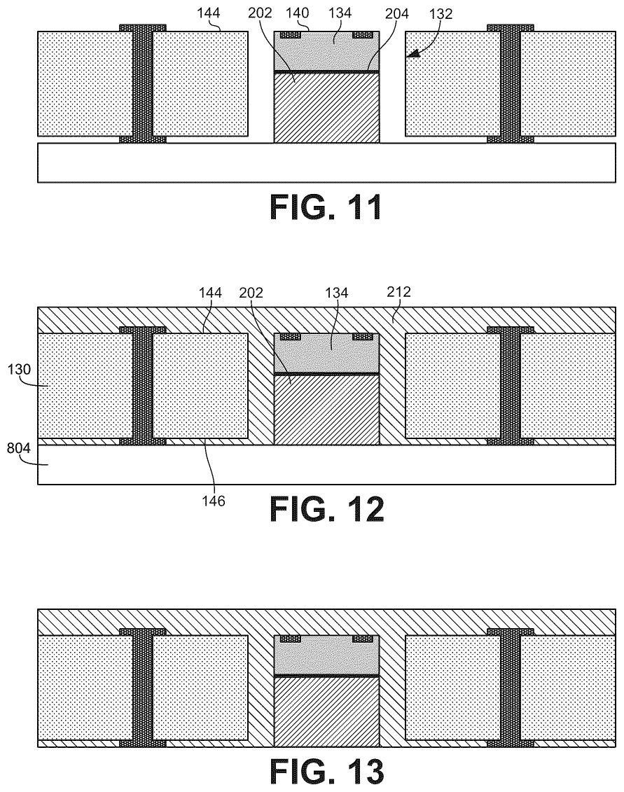

At block 412, the substrate core 130 is positioned on the carrier 804 so that the pedestal 202 is within the cavity 132. FIG. 10 illustrates this stage of the manufacturing process with the pedestal 202 inside the cavity 132. At block 414, a semiconductor device (e.g., a semiconductor die) is attached onto the pedestal. FIG. 11 illustrates this stage of the manufacturing process with the semiconductor device 134 attached to the pedestal 202 with the adhesive 204. As shown in the illustrated example, due to the precise height or thickness 210 of the pedestal 202, when the semiconductor device 134 is placed thereon, the first die surface 140 of the semiconductor device 134 is substantially flush with the first core surface 144 of the substrate core 130.

At block 416, an adhesive material is deposited to encapsulate the semiconductor device 134. FIG. 12 illustrates this stage of the manufacturing process with the semiconductor device 134 encapsulated by the adhesive material 212. As shown in FIG. 12, in this example, the adhesive material 212 also encapsulates the pedestal 202 and extends along the first and second core surface 144, 146 of the substrate core 130. The adhesive material 212 can be deposited via lamination, coating, and/or dispensed in the cavity through any suitable encapsulation process (e.g., vacuum lamination, liquid coating, molding process, etc.). At block 418, the adhesive material 212 is cured (e.g., hardened). In some examples, the adhesive material 212 is cured by the application of heat (e.g., the assembly undergoes a thermal treatment). In some examples, the adhesive material is cured by the application of light (e.g., UV irradiation). At block 420, the carrier 804 is removed. FIG. 13 illustrates this stage of the manufacturing process. In some examples, the carrier 804 is treated with a debonding film prior to the deposition of the layer of material 802 (at block 408) and prior to the placement of the substrate core 130 (at block 412) to facilitate the subsequent removal of the carrier 804.

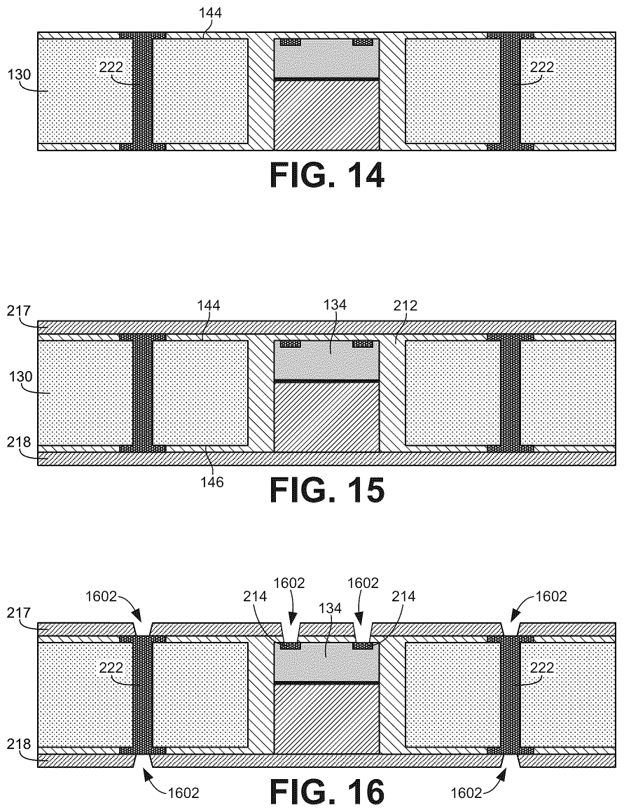

At block 422, excess portions of the adhesive material 212 are removed. FIG. 14 illustrates this stage of the manufacturing process where the adhesive material 212 has been removed to expose the ends of the PTHs 222 at the first core surface 146. In some examples, the adhesive material 212 can be removed via grinding, planarization, and/or any other suitable manner. At block 424, build-up film is added over the semiconductor device 134 and the outer surfaces of the substrate core 130. FIG. 15 illustrates this stage of the manufacturing process where the first and second dielectric layers 217, 218 are positioned along the first and second core surfaces 144, 146 of the substrate core 130. More particularly, in this example, the first and second dielectric layers 217, 218 extend across the portion of the adhesive material 212 that extends along the core surfaces 144, 146. In some examples, the first and second dielectric layers 217, 218 are added through a lamination process.

At block 426, openings 1602 are created in the build-up film (e.g., the first and second dielectric layers 217, 218) to expose contact pads on the semiconductor device 134. FIG. 16 illustrates this stage of the manufacturing process where openings 1602 expose the contact pads 214 on the semiconductor device 134. Further, in this example, additional openings 1602 expose the ends of the PTHs 222. In some examples, the openings 1602 are created through a laser drilling process. Thereafter, at block 428, conductive material (e.g., copper) is deposited in the openings 1602. FIG. 2, detailed above, illustrates the result of this stage of the manufacturing process, and represents the completion of the example method of FIG. 4 to fabricate the package substrate 110 to the point shown in FIG. 2. Additional processing may proceed to complete the fabrication of the buildup regions 128 and/or to construct the complete IC package 100 of FIG. 1.

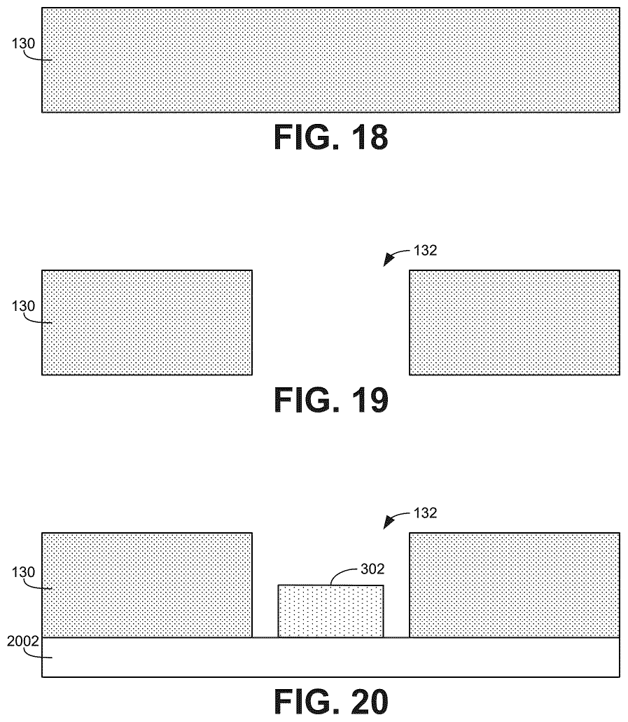

FIG. 17 is a flowchart representative of an example method 1700 to produce the example package substrate 100 of FIG. 1 according to the example implementation 300 of FIG. 3. In some examples, some or all of the operations outlined in the example method of FIG. 17 are performed automatically by fabrication equipment that is programmed to perform the operations. Although the example method of manufacture is described with reference to the flowchart illustrated in FIG. 17, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example. FIGS. 18-27 illustrate the example package substrate 110 at different stages of manufacture during the implementation of the method 1700 of FIG. 17.

The example method 1700 of FIG. 17 begins at block 1702 by providing a substrate core. FIG. 18 illustrates the example substrate core 130 at this stage in the manufacturing process. At block 1704, a cavity is created in the substrate core 130. FIG. 19 illustrates this stage of the manufacturing process with the cavity 132 extending through the substrate core 130. At block 1706, the substrate core 130 is positioned on a carrier. At block 1708, a pedestal is positioned on the carrier within the cavity 132 of the substrate core 130. FIG. 20 illustrates the stage of the manufacturing process following blocks 1706 and 1708 with the pedestal 302 inside the cavity 132 of the substrate core 130 on a carrier 2002. In this example, the pedestal 302 is assumed to be a unitary structure (e.g., structural silicon, a piece of glass, a ceramic, etc.) that is picked and placed into the cavity 132 after placement of the substrate core 130. However, in other examples, the pedestal 302 can be picked and placed prior to the placement of the substrate core 130 around the pedestal 302. Furthermore, in some examples, the pedestal 302 can be fabricated on the surface of the carrier 2002 in a manner similar to the pedestal 202 of FIG. 2 as discussed above.

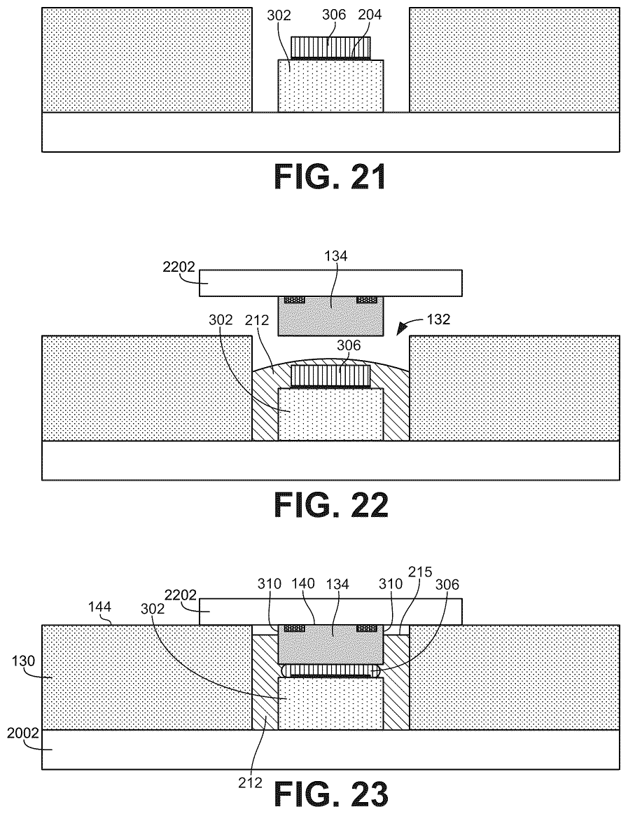

At block 1710, a compressible material is attached to the pedestal 302. FIG. 21 illustrates this stage of the manufacturing process with the compressible material 306 attached to the pedestal 302 with the adhesive 308. In some examples, the compressible material 306 can be attached to the pedestal 302 prior to insertion into the cavity 132. That is, in some examples, block 1710 is implemented prior to block 1708. At block 1712, an adhesive material is deposited into the cavity 132. FIG. 22 illustrates this stage of the manufacturing process with the adhesive material 212 deposited within the cavity 132. The adhesive material 212 can be deposited via lamination, coating, and/or dispensed in the cavity through any suitable encapsulation process (e.g., vacuum lamination, liquid coating, molding process, etc.). Notably, the adhesive material 212 does not completely fill the cavity 132 but is added in a quantity sufficient to encapsulate the pedestal and at least partially surround the compressible material 306. The cavity 132 is not completely filled with the adhesive material 212 because the semiconductor device 134 is yet to be inserted and will displace some of the adhesive material 212. Specifically, FIG. 22 shows a bond head 2202 holding the semiconductor device 134 ready to be inserted into the cavity 132.

At block 1714, the semiconductor device 134 is pressed against the compressible material 306 until the semiconductor device 134 is substantially flush with the outer surface of the substrate core 130. FIG. 23 illustrates this stage of the manufacturing process with the semiconductor device 134 compressing the compressible material 306 against the pedestal 302. As a result, as shown in FIG. 23, the compressible material deforms (e.g., flattens vertically and expands laterally) and the adhesive material 212 is displaced to surround the lateral edges 310 of the semiconductor device 134. In this example, the compressible material 306 expands laterally when compressed but remains with a width that is less than the width of the semiconductor device 134. This is achieved by using a compressible material 306 that has an initial width (e.g., before compression) less than the width of the semiconductor device 134. In other examples, the compressible material 306 may be as wide as or wider than the width of the semiconductor device 134. In such examples, as the compressible material 306 deforms when compressed, the compressible material 306 may extend laterally beyond the lateral edges 310 of the semiconductor device 134 and/or beyond laterally edges of the pedestal 302.

As discussed above, in this example, the volume of the adhesive material 212 deposited within the cavity 132 is controlled so that the first (e.g., top) adhesive surface 215 remains spaced apart from the bond head 2202 to prevent contamination of the bond head 2202. Thus, in this example, the first adhesive surface 215 is recessed relative to the first core surface 144 against which the bond head 2202 is pressed. In this example, the bond head 2202 includes a front face or plate that is pressed against the first core surface 144 to position the first die surface 140 substantially flush with the first core surface 144. The flush relationship of these surfaces 140, 144 is achieved because the compressible material 306 urges the semiconductor device 134 against the bond head 2202 which is aligned with (e.g., engaging, interfacing, pressed against, etc.) the first core surface 144.

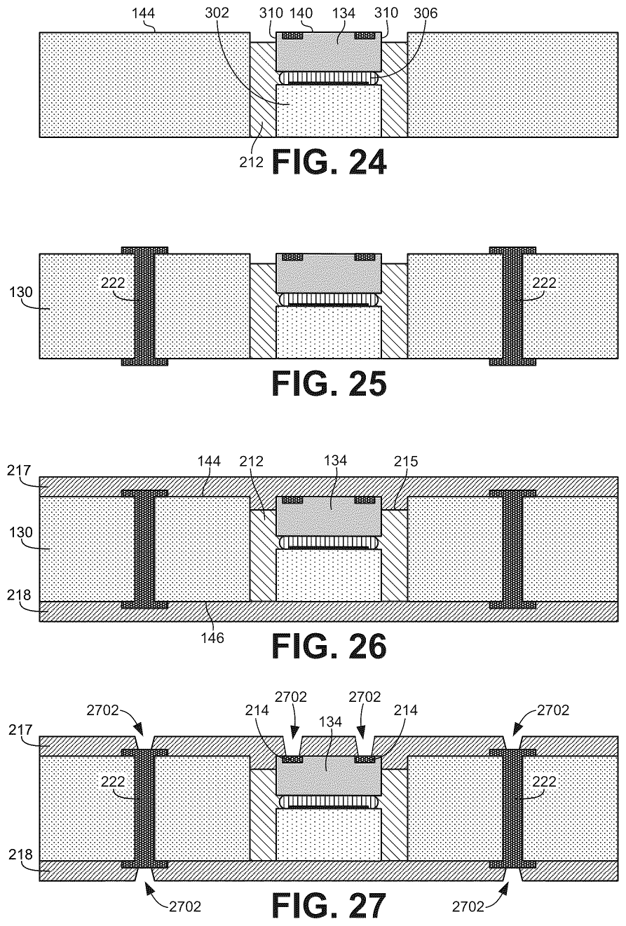

At block 1716, the adhesive material 212 is cured (e.g., hardened). In some examples, the adhesive material 212 is cured by the application of heat (e.g., the assembly undergoes a thermal treatment). In some examples, the adhesive material is cured by the application of light (e.g., UV irradiation). At block 1718, the carrier 2002 and the bond head 2202 are removed. FIG. 24 illustrates this stage of the manufacturing process. Inasmuch as the adhesive material 212 surrounds the lateral edges 310 of the semiconductor device 134 and the adhesive material 306 has been cured, the compressible material 306 will not be able to expand. Rather, the assembly will remain in a fixed position corresponding to when the bond head 2202 was still present. Thus, the semiconductor device 134 will remain in flush relationship with the first core surface 144 of the substrate core 130. In some examples, the carrier 2002 is treated with a debonding film prior to the positioning of the substrate core 130 (at block 1706) and prior to the positioning of the pedestal 302 (at block 1708) to facilitate the subsequent removal of the carrier 2002.

At block 1720, the surface of the substrate core 130 is patterned with conductive material (e.g., copper) and plated through holes (PTHs) are added. FIG. 25 illustrates this stage of the manufacturing process with the example PTHs 222 extending through the substrate core 130 (with associated conductive pads at each end). While two PTHs 222 are shown in this illustrated example, any other number of PTHs may be used. Further, any other portions (e.g., traces, pads, etc.) of conductive material can be patterned on one or both surfaces of the core 130. Notably, in this example, the PTHs 222 are added after the semiconductor device 134 is embedded in the cavity, whereas the PTHs 222 associated with the example method 400 of FIG. 4 were added before the semiconductor device 134 was added. In some examples, the process followed in FIG. 4 with respect to the PTHs 222 can be applied to the example method of FIG. 17. Likewise, in some examples, the process followed in FIG. 17 with respect to the PTHs 222 can be applied to the example method of FIG. 4. In other words, the example PTHs 222 can be added at any suitable point in the fabrication process.

At block 1722, build-up film is added over the semiconductor device 134 and the outer surfaces of the substrate core 130. FIG. 26 illustrates this stage of the manufacturing process where the first and second dielectric layers 217, 218 are positioned along the first and second core surfaces 144, 146 of the substrate core 130. In this example, as shown in FIG. 26, the first dielectric layer 217 extends into the cavity to fill the space between the recessed first adhesive surface 215 and the first core surface 144. In some examples, the first and second dielectric layers 217, 218 are added through a lamination process.

At block 1724, openings 2702 are created in the build-up film (e.g., the first and second dielectric layers 217, 218) to expose contact pads on the semiconductor device 134. FIG. 27 illustrates this stage of the manufacturing process where openings 2702 expose the contact pads 214 on the semiconductor device 134. Further, in this example, additional openings 2702 expose the ends of the PTHs 222. In some examples, the openings 2702 are created through a laser drilling process. Thereafter, at block 1726, conductive material (e.g., copper) is deposited in the openings 2702. FIG. 3, detailed above, illustrates the result of this stage of the manufacturing process, and represents the completion of the example method of FIG. 17 to fabricate the package substrate 110 to the point shown in FIG. 3. Additional processing may proceed to complete the fabrication of the buildup regions 128 and/or to construct the complete IC package 100 of FIG. 1.

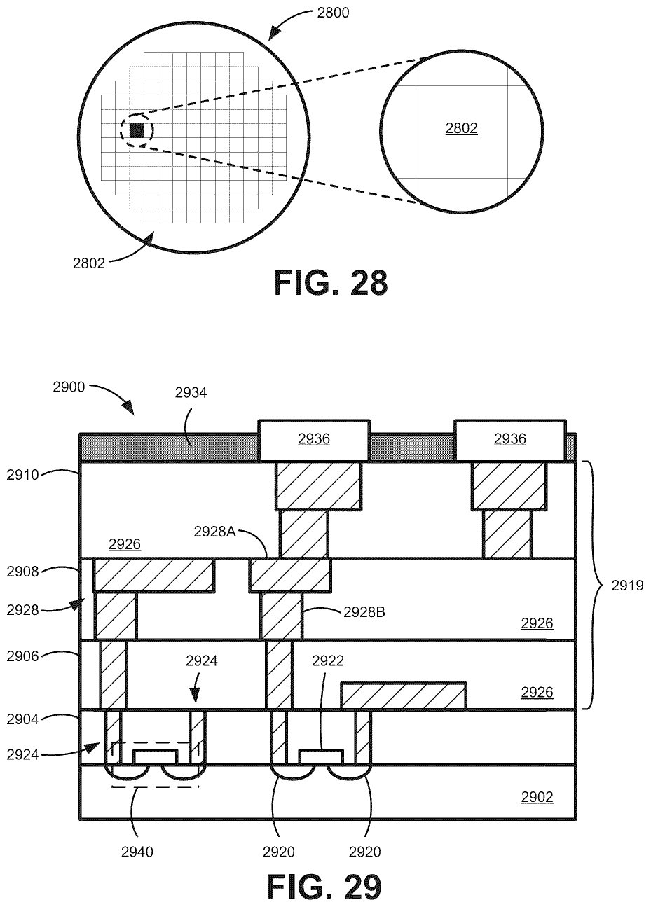

The example IC package 100 of FIG. 1 implemented with the package substrate 110 constructed in accordance with the example implementations 200, 300 of FIGS. 2 and 3 disclosed herein may be included in any suitable electronic component. FIGS. 28-31 illustrate various examples of apparatus that may include or be included in the IC package 100 disclosed herein.

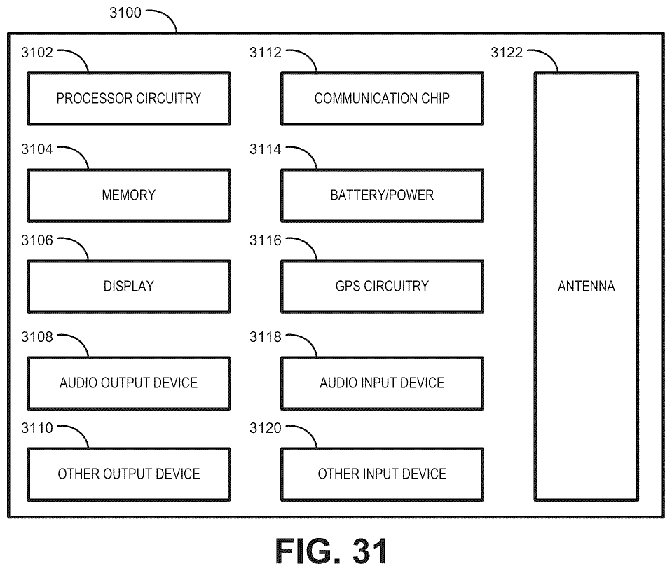

FIG. 28 is a top view of a wafer 2800 and dies 2802 that may be included in the IC package 100 of FIG. 1 (e.g., as any suitable ones of the dies 106, 108 and/or the semiconductor device 134). The wafer 2800 includes semiconductor material and one or more dies 2802 having circuitry. Each of the dies 2802 may be a repeating unit of a semiconductor product. After the fabrication of the semiconductor product is complete, the wafer 2800 may undergo a singulation process in which the dies 2802 are separated from one another to provide discrete “chips.” The die 2802 includes one or more transistors (e.g., some of the transistors 2940 of FIG. 29, discussed below), supporting circuitry to route electrical signals to the transistors, passive components (e.g., traces, resistors, capacitors, inductors, and/or other circuitry), and/or any other components. In some examples, the die 2802 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 2802. For example, a memory array of multiple memory circuits may be formed on a same die 2802 as programmable circuitry (e.g., the processor circuitry 3102 of FIG. 31) and/or other logic circuitry. Such memory may store information for use by the programmable circuitry. The example IC package 100 disclosed herein may be manufactured using a die-to-wafer assembly technique in which some dies are attached to a wafer 2800 that include others of the dies, and the wafer 2800 is subsequently singulated.

FIG. 29 is a cross-sectional side view of an IC device 2900 that may be included in the example IC package 100 (e.g., in any one of the dies 106, 108 and/or the semiconductor device 134). One or more of the IC devices 2900 may be included in one or more dies 2802 (FIG. 28). The IC device 2900 may be formed on a die substrate 2902 (e.g., the wafer 2800 of FIG. 28) and may be included in a die (e.g., the die 2802 of FIG. 28). The die substrate 2902 may be a semiconductor substrate including semiconductor materials including, for example, n-type or p-type materials systems (or a combination of both). The die substrate 2902 may include, for example, a crystalline substrate formed using a bulk silicon or a silicon-on-insulator (SOI) substructure. In some examples, the die substrate 2902 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 2902. Although a few examples of materials from which the die substrate 2902 may be formed are described here, any material that may serve as a foundation for an IC device 2900 may be used. The die substrate 2902 may be part of a singulated die (e.g., the dies 2802 of FIG. 28) or a wafer (e.g., the wafer 2800 of FIG. 28).

The IC device 2900 may include one or more device layers 2904 disposed on and/or above the die substrate 2902. The device layer 2904 may include features of one or more transistors 2940 (e.g., metal oxide semiconductor field-effect transistors (MOSFETs)) formed on the die substrate 2902. The device layer 2904 may include, for example, one or more source and/or drain (S/D) regions 2920, a gate 2922 to control current flow between the S/D regions 2920, and one or more S/D contacts 2924 to route electrical signals to/from the S/D regions 2920. The transistors 2940 may include additional features not depicted for the sake of clarity, such as device isolation regions, gate contacts, and the like. The transistors 2940 are not limited to the type and configuration depicted in FIG. 29 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 2940 may include a gate 2922 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 2940 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 2940 along the source-channel-drain direction, the gate electrode may include a U-shaped structure that includes a bottom portion substantially parallel to the surface of the die substrate 2902 and two sidewall portions that are substantially perpendicular to the top surface of the die substrate 2902. In other examples, at least one of the metal layers that form the gate electrode may be a planar layer that is substantially parallel to the top surface of the die substrate 2902 and does not include sidewall portions substantially perpendicular to the top surface of the die substrate 2902. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 2920 may be formed within the die substrate 2902 adjacent to the gate 2922 of corresponding transistor(s) 2940. The S/D regions 2920 may be formed using an implantation/diffusion process or an etching/deposition process, for example. In the former process, dopants such as boron, aluminum, antimony, phosphorous, or arsenic may be ion-implanted into the die substrate 2902 to form the S/D regions 2920. An annealing process that activates the dopants and causes them to diffuse farther into the die substrate 2902 may follow the ion-implantation process. In the latter process, the die substrate 2902 may first be etched to form recesses at the locations of the S/D regions 2920. An epitaxial deposition process may then be carried out to fill the recesses with material that is used to fabricate the S/D regions 2920. In some implementations, the S/D regions 2920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 2920 may be formed using one or more alternate semiconductor materials such as germanium or a group III-V material or alloy. In further examples, one or more layers of metal and/or metal alloys may be used to form the S/D regions 2920.

Electrical signals, such as power and/or input/output (I/O) signals, may be routed to and/or from the devices (e.g., transistors 2940) of the device layer 2904 through one or more interconnect layers disposed on the device layer 2904 (illustrated in FIG. 29 as interconnect layers 2906-2910). For example, electrically conductive features of the device layer 2904 (e.g., the gate 2922 and the S/D contacts 2924) may be electrically coupled with the interconnect structures 2928 of the interconnect layers 2906-2910. The one or more interconnect layers 2906-2910 may form a metallization stack (also referred to as an “ILD stack”) 2919 of the IC device 2900.

The interconnect structures 2928 may be arranged within the interconnect layers 2906-2910 to route electrical signals according to a wide variety of designs (in particular, the arrangement is not limited to the particular configuration of interconnect structures 2928 depicted in FIG. 29). Although a particular number of interconnect layers 2906-2910 is depicted in FIG. 29, examples of the present disclosure include IC devices having more or fewer interconnect layers than depicted.

In some examples, the interconnect structures 2928 may include lines 2928a and/or vias 2928b filled with an electrically conductive material such as a metal. The lines 2928a may be arranged to route electrical signals in a direction of a plane that is substantially parallel with a surface of the die substrate 2902 upon which the device layer 2904 is formed. For example, the lines 2928a may route electrical signals in a direction in and/or out of the page from the perspective of FIG. 29. The vias 2928b may be arranged to route electrical signals in a direction of a plane that is substantially perpendicular to the surface of the die substrate 2902 upon which the device layer 2904 is formed. In some examples, the vias 2928b may electrically couple lines 2928a of different interconnect layers 2906-2910 together.

The interconnect layers 2906-2910 may include a dielectric material 2926 disposed between the interconnect structures 2928, as shown in FIG. 29. In some examples, the dielectric material 2926 disposed between the interconnect structures 2928 in different ones of the interconnect layers 2906-2910 may have different compositions; in other examples, the composition of the dielectric material 2926 between different interconnect layers 2906-2910 may be the same.

A first interconnect layer 2906 (referred to as Metal 1 or “M1”) may be formed directly on the device layer 2904. In some examples, the first interconnect layer 2906 may include lines 2928a and/or vias 2928b, as shown. The lines 2928a of the first interconnect layer 2906 may be coupled with contacts (e.g., the S/D contacts 2924) of the device layer 2904.

A second interconnect layer 2908 (referred to as Metal 2 or “M2”) may be formed directly on the first interconnect layer 2906. In some examples, the second interconnect layer 2908 may include vias 2928b to couple the lines 2928a of the second interconnect layer 2908 with the lines 2928a of the first interconnect layer 2906. Although the lines 2928a and the vias 2928b are structurally delineated with a line within each interconnect layer (e.g., within the second interconnect layer 2908) for the sake of clarity, the lines 2928a and the vias 2928b may be structurally and/or materially contiguous (e.g., simultaneously filled during a dual-damascene process) in some examples.

A third interconnect layer 2910 (referred to as Metal 3 or “M3”) (and additional interconnect layers, as desired) may be formed in succession on the second interconnect layer 2908 according to similar techniques and/or configurations described in connection with the second interconnect layer 2908 or the first interconnect layer 2906. In some examples, the interconnect layers that are “higher up” in the metallization stack 2919 in the IC device 2900 (i.e., further away from the device layer 2904) may be thicker.

The IC device 2900 may include a solder resist material 2934 (e.g., polyimide or similar material) and one or more conductive contacts 2936 formed on the interconnect layers 2906-2910. In FIG. 29, the conductive contacts 2936 are illustrated as taking the form of bond pads. The conductive contacts 2936 may be electrically coupled with the interconnect structures 2928 and configured to route the electrical signals of the transistor(s) 2940 to other external devices. For example, solder bonds may be formed on the one or more conductive contacts 2936 to mechanically and/or electrically couple a chip including the IC device 2900 with another component (e.g., a circuit board). The IC device 2900 may include additional or alternate structures to route the electrical signals from the interconnect layers 2906-2910; for example, the conductive contacts 2936 may include other analogous features (e.g., posts) that route the electrical signals to external components.

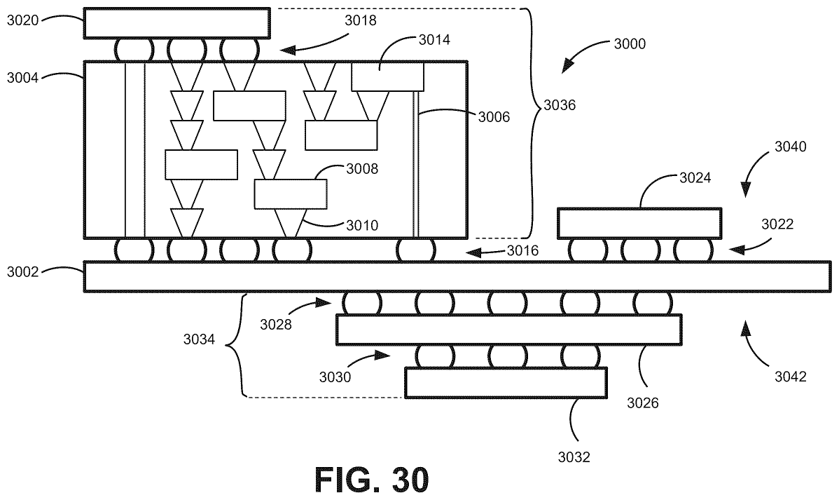

FIG. 30 is a cross-sectional side view of an IC device assembly 3000 that may include the IC package 100 disclosed herein. In some examples, the IC device assembly corresponds to the IC package 100. The IC device assembly 3000 includes a number of components disposed on a circuit board 3002 (which may be, for example, a motherboard). The IC device assembly 3000 includes components disposed on a first face 3040 of the circuit board 3002 and an opposing second face 3042 of the circuit board 3002; generally, components may be disposed on one or both faces 3040 and 3042. Any of the IC packages discussed below with reference to the IC device assembly 2200 may take the form of the example IC package 100 of FIG. 1 as constructed in accordance with the example implementations 200, 300 of FIGS. 2 and/or 3.

In some examples, the circuit board 3002 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 3002. In other examples, the circuit board 3002 may be a non-PCB substrate.

The IC device assembly 3000 illustrated in FIG. 30 includes a package-on-interposer structure 3036 coupled to the first face 3040 of the circuit board 3002 by coupling components 3016. The coupling components 3016 may electrically and mechanically couple the package-on-interposer structure 3036 to the circuit board 3002, and may include solder balls (as shown in FIG. 30), male and female portions of a socket, an adhesive, an underfill material, and/or any other suitable electrical and/or mechanical coupling structure.

The package-on-interposer structure 3036 may include an IC package 3020 coupled to an interposer 3004 by coupling components 3018. The coupling components 3018 may take any suitable form for the application, such as the forms discussed above with reference to the coupling components 3016. Although a single IC package 3020 is shown in FIG. 30, multiple IC packages may be coupled to the interposer 3004; indeed, additional interposers may be coupled to the interposer 3004. The interposer 3004 may provide an intervening substrate used to bridge the circuit board 3002 and the IC package 3020. The IC package 3020 may be or include, for example, a die (the die 2802 of FIG. 28), an IC device (e.g., the IC device 2900 of FIG. 29), or any other suitable component. Generally, the interposer 3004 may spread a connection to a wider pitch or reroute a connection to a different connection. For example, the interposer 3004 may couple the IC package 3020 (e.g., a die) to a set of BGA conductive contacts of the coupling components 3016 for coupling to the circuit board 3002. In the example illustrated in FIG. 30, the IC package 3020 and the circuit board 3002 are attached to opposing sides of the interposer 3004; in other examples, the IC package 3020 and the circuit board 3002 may be attached to a same side of the interposer 3004. In some examples, three or more components may be interconnected by way of the interposer 3004.

In some examples, the interposer 3004 may be formed as a PCB, including multiple metal layers separated from one another by layers of dielectric material and interconnected by electrically conductive vias. In some examples, the interposer 3004 may be formed of an epoxy resin, a fiberglass-reinforced epoxy resin, an epoxy resin with inorganic fillers, a ceramic material, or a polymer material such as polyimide. In some examples, the interposer 3004 may be formed of alternate rigid or flexible materials that may include the same materials described above for use in a semiconductor substrate, such as silicon, germanium, and other group III-V and group IV materials. The interposer 3004 may include metal interconnects 3008 and vias 3010, including but not limited to through-silicon vias (TSVs) 3006. The interposer 3004 may further include embedded devices 3014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3004. The package-on-interposer structure 3036 may take the form of any of the package-on-interposer structures known in the art.

The IC device assembly 3000 may include an IC package 3024 coupled to the first face 3040 of the circuit board 3002 by coupling components 3022. The coupling components 3022 may take the form of any of the examples discussed above with reference to the coupling components 3016, and the IC package 3024 may take the form of any of the examples discussed above with reference to the IC package 3020.

The IC device assembly 3000 illustrated in FIG. 30 includes a package-on-package structure 3034 coupled to the second face 3042 of the circuit board 3002 by coupling components 3028. The package-on-package structure 3034 may include a first IC package 3026 and a second IC package 3032 coupled together by coupling components 3030 such that the first IC package 3026 is disposed between the circuit board 3002 and the second IC package 3032. The coupling components 3028, 3030 may take the form of any of the examples of the coupling components 3016 discussed above, and the IC packages 3026, 3032 may take the form of any of the examples of the IC package 3020 discussed above. The package-on-package structure 3034 may be configured in accordance with any of the package-on-package structures known in the art.

FIG. 31 is a block diagram of an example electrical device 3100 that may include one or more of the example IC package 100 constructed in accordance with the example implementations 200, 300 of FIGS. 2 and/or 3. For example, any suitable ones of the components of the electrical device 3100 may include one or more of the device assemblies 3000, IC devices 2900, or dies 2802 disclosed herein, and may be arranged in the example IC package 100. A number of components are illustrated in FIG. 31 as included in the electrical device 3100, but any one or more of these components may be omitted or duplicated, as suitable for the application. In some examples, some or all of the components included in the electrical device 3100 may be attached to one or more motherboards. In some examples, some or all of these components are fabricated onto a single system-on-a-chip (SoC) die.

Additionally, in various examples, the electrical device 3100 may not include one or more of the components illustrated in FIG. 31, but the electrical device 3100 may include interface circuitry for coupling to the one or more components. For example, the electrical device 3100 may not include a display 3106, but may include display interface circuitry (e.g., a connector and driver circuitry) to which a display 3106 may be coupled. In another set of examples, the electrical device 3100 may not include an audio input device 3118 (e.g., microphone) or an audio output device 3108 (e.g., a speaker, a headset, earbuds, etc.), but may include audio input or output device interface circuitry (e.g., connectors and supporting circuitry) to which an audio input device 3118 or audio output device 3108 may be coupled.

The electrical device 3100 may include programmable circuitry 3102 (e.g., one or more processing devices). The programmable circuitry 3102 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 3100 may include a memory 3104, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 3104 may include memory that shares a die with the programmable circuitry 3102. This memory may be used as cache memory and may include embedded dynamic random access memory (eDRAM) or spin transfer torque magnetic random access memory (STT-MRAM).

In some examples, the electrical device 3100 may include a communication chip 3112 (e.g., one or more communication chips). For example, the communication chip 3112 may be configured for managing wireless communications for the transfer of data to and from the electrical device 3100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 3112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 3112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 3112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 3112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 3112 may operate in accordance with other wireless protocols in other examples. The electrical device 3100 may include an antenna 3122 to facilitate wireless communications and/or to receive other wireless communications (such as AM or FM radio transmissions).

In some examples, the communication chip 3112 may manage wired communications, such as electrical, optical, or any other suitable communication protocols (e.g., the Ethernet). As noted above, the communication chip 3112 may include multiple communication chips. For instance, a first communication chip 3112 may be dedicated to shorter-range wireless communications such as Wi-Fi or Bluetooth, and a second communication chip 3112 may be dedicated to longer-range wireless communications such as global positioning system (GPS), EDGE, GPRS, CDMA, WiMAX, LTE, EV-DO, or others. In some examples, a first communication chip 3112 may be dedicated to wireless communications, and a second communication chip 3112 may be dedicated to wired communications.

The electrical device 3100 may include battery/power circuitry 3114. The battery/power circuitry 3114 may include one or more energy storage devices (e.g., batteries or capacitors) and/or circuitry for coupling components of the electrical device 3100 to an energy source separate from the electrical device 3100 (e.g., AC line power).

The electrical device 3100 may include a display 3106 (or corresponding interface circuitry, as discussed above). The display 3106 may include any visual indicators, such as a heads-up display, a computer monitor, a projector, a touchscreen display, a liquid crystal display (LCD), a light-emitting diode display, or a flat panel display.

The electrical device 3100 may include an audio output device 3108 (or corresponding interface circuitry, as discussed above). The audio output device 3108 may include any device that generates an audible indicator, such as speakers, headsets, or earbuds.

The electrical device 3100 may include an audio input device 3118 (or corresponding interface circuitry, as discussed above). The audio input device 3118 may include any device that generates a signal representative of a sound, such as microphones, microphone arrays, or digital instruments (e.g., instruments having a musical instrument digital interface (MIDI) output).

The electrical device 3100 may include GPS circuitry 3116. The GPS circuitry 3116 may be in communication with a satellite-based system and may receive a location of the electrical device 3100, as known in the art.

The electrical device 3100 may include any other output device 3110 (or corresponding interface circuitry, as discussed above). Examples of the other output device 3110 may include an audio codec, a video codec, a printer, a wired or wireless transmitter for providing information to other devices, or an additional storage device.

The electrical device 3100 may include any other input device 3120 (or corresponding interface circuitry, as discussed above). Examples of the other input device 3120 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 3100 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 3100 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor component (e.g., a transistor), a semiconductor die containing a semiconductor component, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor component) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor components are often used in orientation different than their orientation during fabrication. Thus, when referring to a semiconductor component (e.g., a transistor), a semiconductor die containing a semiconductor component, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable semiconductor devices e.g., semiconductor dies) to be embedded within a cavity of a substrate core. More particularly, examples disclosed herein resolve challenges arising from a mismatch in thickness of such semiconductor devices relatively to larger (e.g., thicker) substrate cores by providing a pedestal or spacer that fills up much of the empty space within the cavity to reduce the amount of adhesive material used to secure the semiconductor device in place. Furthermore, in some examples, a compressible material is used to urge the semiconductor device against a flat surface of a bond head or plate that is used when insert the semiconductor device into the cavity to facilitate the positioning of the semiconductor die substantially flush with the outer surface of the substrate core.

Further examples and combinations thereof include the following:

Example 1 includes a package substrate comprising a core having a first surface and a second surface, the core including a cavity extending between the first and second surfaces, a semiconductor die within the cavity, a pedestal within the cavity, and an adhesive within the cavity, the adhesive surrounding the semiconductor die and the pedestal, a material of the pedestal different from a material of the adhesive.

Example 2 includes the package substrate of example 1, wherein the semiconductor die and the pedestal are stacked.

Example 3 includes the package substrate of any one of examples 1 or 2, further including a compressible material between the semiconductor die and the pedestal.

Example 4 includes the package substrate of example 3, wherein the compressible material is held in compression between the semiconductor die and the pedestal.

Example 5 includes the package substrate of any one of examples 3 or 4, wherein the compressible material extends beyond laterally edges of the semiconductor die in a direction perpendicular to the first surface.

Example 6 includes the package substrate of any one of examples 1-5, wherein the first surface is a first core surface and the second surface is a second core surface, the semiconductor die including a first die surface and a second die surface opposite the first die surface, the second die surface facing the pedestal, the first die surface substantially flush with the first core surface.

Example 7 includes the package substrate of any one of examples 1-6, wherein the first surface is a first core surface and the second surface is a second core surface, the adhesive extends from a first adhesive surface to a second adhesive surface, the first adhesive surface adjacent to the first core surface, the second adhesive surface adjacent to the second core surface, the first adhesive surface recessed into the cavity relative to the first core surface.

Example 8 includes the package substrate of example 7, further including a build-up film on the first core surface, the build-up film extending across the cavity, the build-up film extending into the cavity to contact the first adhesive surface.

Example 9 includes the package substrate of any one of examples 1-8, wherein the pedestal includes a dry film resist material.

Example 10 includes the package substrate of any one of examples 1-8, wherein the pedestal includes a photo-imageable dielectric material.

Example 11 includes the package substrate of any one of examples 1-10, wherein the semiconductor die has a first thickness, and the core has a second thickness, the first thickness less than the second thickness.

Example 12 includes the package substrate of example 11, wherein the first surface is a first core surface and the second surface is a second core surface, the semiconductor die including a first die surface and a second die surface opposite the first die surface, the first die surface aligned with the first core surface such that the second die surface is spaced apart from the second core surface by a first distance corresponding to a difference between the first thickness and the second thickness, the pedestal having a third thickness that extends along a majority of the first distance.

Example 13 includes the package substrate of example 12, wherein the third thickness is greater than the first distance.

Example 14 includes the package substrate of any one of examples 1-13, wherein the semiconductor die includes a deep trench capacitor.

Example 15 includes a package substrate comprising a core having a cavity extending between first and second surfaces of the core, a semiconductor device within the cavity, the semiconductor device adjacent to the first surface of the core and spaced apart from the second surface of the core, a spacer within the cavity, the spacer adjacent to the second surface of the core and spaced apart from the first surface of the core, and an encapsulant within the cavity around the semiconductor device and the spacer.

Example 16 includes the package substrate of example 15, further including a compressible material between the semiconductor device and the spacer.

Example 17 includes the package substrate of example 16, wherein the encapsulant is to be spaced apart from the first surface of the core.

Example 18 includes an apparatus comprising a package substrate, a first semiconductor die on the package substrate, a second semiconductor die within a substrate core of the package substrate, the second semiconductor die electrically coupled to the first semiconductor die, and a pedestal within the substrate core adjacent to the second semiconductor die, and a mold compound at lateral edges of the second semiconductor and the pedestal, the mold compound including a material not present in the pedestal.

Example 19 includes the apparatus of example 18, further including a compressible material positioned between the second semiconductor die and the pedestal.

Example 20 includes the apparatus of any one of examples 18 or 19, further including at least one of a display or a keyboard.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A package substrate comprising:
a core having a first surface and a second surface, the core including a cavity extending between the first and second surfaces;
a semiconductor die within the cavity;
a pedestal within the cavity; and
an adhesive within the cavity, the adhesive surrounding the semiconductor die and the pedestal, a material of the pedestal different from a material of the adhesive.

2. The package substrate of claim 1, wherein the semiconductor die and the pedestal are stacked.

3. The package substrate of claim 1, further including a compressible material between the semiconductor die and the pedestal.

4. The package substrate of claim 3, wherein the compressible material is held in compression between the semiconductor die and the pedestal.

5. The package substrate of claim 3, wherein the compressible material extends beyond laterally edges of the semiconductor die in a direction perpendicular to the first surface.

6. The package substrate of claim 1, wherein the first surface is a first core surface and the second surface is a second core surface, the semiconductor die including a first die surface and a second die surface opposite the first die surface, the second die surface facing the pedestal, the first die surface substantially flush with the first core surface.

7. The package substrate of claim 1, wherein the first surface is a first core surface and the second surface is a second core surface, the adhesive extends from a first adhesive surface to a second adhesive surface, the first adhesive surface adjacent to the first core surface, the second adhesive surface adjacent to the second core surface, the first adhesive surface recessed into the cavity relative to the first core surface.

8. The package substrate of claim 7, further including a build-up film on the first core surface, the build-up film extending across the cavity, the build-up film extending into the cavity to contact the first adhesive surface.

9. The package substrate of claim 1, wherein the pedestal includes a dry film resist material.

10. The package substrate of claim 1, wherein the pedestal includes a photo-imageable dielectric material.

11. The package substrate of claim 1, wherein the semiconductor die has a first thickness, and the core has a second thickness, the first thickness less than the second thickness.

12. The package substrate of claim 11, wherein the first surface is a first core surface and the second surface is a second core surface, the semiconductor die including a first die surface and a second die surface opposite the first die surface, the first die surface aligned with the first core surface such that the second die surface is spaced apart from the second core surface by a first distance corresponding to a difference between the first thickness and the second thickness, the pedestal having a third thickness that extends along a majority of the first distance.

13. The package substrate of claim 12, wherein the third thickness is greater than the first distance.

14. The package substrate of claim 1, wherein the semiconductor die includes a deep trench capacitor.

15. A package substrate comprising:
a core having a cavity extending between first and second surfaces of the core;
a semiconductor device within the cavity, the semiconductor device adjacent to the first surface of the core and spaced apart from the second surface of the core;
a spacer within the cavity, the spacer adjacent to the second surface of the core and spaced apart from the first surface of the core; and
an encapsulant within the cavity around the semiconductor device and the spacer.

16. The package substrate of claim 15, further including a compressible material between the semiconductor device and the spacer.

17. The package substrate of claim 16, wherein the encapsulant is spaced apart from the first surface of the core.

18. An apparatus comprising:
a package substrate;
a first semiconductor die on the package substrate;
a second semiconductor die within a substrate core of the package substrate, the second semiconductor die electrically coupled to the first semiconductor die; and
a pedestal within the substrate core adjacent to the second semiconductor die; and
a mold compound at lateral edges of the second semiconductor and the pedestal, the mold compound including a material not present in the pedestal.

19. The apparatus of claim 18, further including a compressible material between the second semiconductor die and the pedestal.

20. The apparatus of claim 18, further including at least one of a display or a keyboard.
